(19) United States
(12) Patent Application Publication
(10) Pub. No.: US 2010/0126566 A1
(43) Pub. Date: May 27, 2010

(54) SURFACE PLASMON WAVELENGTH CONVERTER

(75) Inventor: Jin Ji, Boston, MA (US)

Correspondence Address: Milstein Zhang & Wu LLC, 49 Lexington Street, Suite 6, Newton, MA, 02465-1062, US

(73) Assignee: Lightwave Power, Inc., Cambridge, MA (US)

(21) Appl. No.: 12/621,928

(22) Filed: Nov. 19, 2009

Related U.S. Application Data
(60) Provisional application No. 61/116,755, filed on Nov. 21, 2008.

(51) Int. Cl. G02F 1/35; H01L 31/02

(52) U.S. Cl. 136/252; 359/326

(57) ABSTRACT

A surface plasmon wavelength converter device includes a metallic film which has a plurality of nanofeatures. A wavelength conversion layer having a plurality of centers is disposed adjacent to the metallic film. The surface plasmon wavelength converter device is configured to respond to an incident electromagnetic radiation having a first wavelength by radiating away from the surface plasmon wavelength converter device an electromagnetic radiation having a second wavelength. A surface plasmon wavelength converter device having a metallic film and at least one center disposed in at least one of a plurality of nanofeatures of the metallic film is also described. A surface plasmon wavelength converter device having a transparent conductive oxide (TCO) film having a plurality of metallic nanofeatures, adjacent to a wavelength conversion layer, and a TCO film having a plurality of metallic nanofeatures with at least one center disposed therein is also described.

### CROSS-REFERENCE TO RELATED APPLICATIONS

This application claims priority to and the benefit of co-pending U.S. provisional patent application Ser. No. 61/116,755, PERIODIC OR NON-PERIODIC NANOSTRUCTURES TO CONTROL EMISSION ENVIRONMENT FOR ENHANCED WAVELENGTH SHIFTING EFFICIENCY, filed Nov. 21, 2008, which application is incorporated herein by reference in its entirety. This application is also related to co-pending PCT Application No. PCT/U.S.09/36815, entitled INTEGRATED SOLAR CELL WITH WAVELENGTH CONVERSION LAYERS AND LIGHT GUIDING AND CONCENTRATING LAYERS, filed Mar. 11, 2009, which is incorporated by reference in its entirety.

### FIELD OF THE INVENTION

The invention relates to wavelength converter in general and particularly to a surface plasmon wavelength converter.

### BACKGROUND OF THE INVENTION

FIG. 1 shows an illustration of a solar cell according to the prior art. A solar cell 100 is typically made from single crystal silicon. The solar cell 100 has a PN junction 101 to separate photogenerated pairs, a front collection grid 110 which collects current from the illuminated side, and a rear collection grid 120 which collects current from the rear side. Photons 140 with energy greater than the energy band gap are absorbed. Photons 145 with energy less than the band gap are not absorbed. A material 130 (e.g. Er-doped NaYF4) placed on the back surface of the cell can absorb photons 145 and re-emit a photon 150 that has energy greater than the silicon energy gap. Material 130 thus “upconverts” incident photons 145 so that the resultant photons 150 can be absorbed by the solar cell and thereby increase the short circuit current of solar cell 100. Such prior art wavelength conversion layers are expensive to manufacture and relatively inefficient.

What is needed, therefore, is a more efficient wavelength conversion device.

### SUMMARY OF THE INVENTION

In one aspect, the invention relates to a surface plasmon wavelength converter device which includes a metallic film having a plurality of nanofeatures. The metallic film has a metallic film first surface and a metallic film second surface. A wavelength conversion layer having a plurality of centers is disposed adjacent to and optically coupled to the first surface of the metallic film. The surface plasmon wavelength converter device is configured to respond to an incident electromagnetic radiation having a first wavelength by radiating away from the surface plasmon wavelength converter device an electromagnetic radiation having a second wavelength.

In one embodiment, the nanofeatures are configured to exhibit intensified fields in response to the surface plasmon waves generated at one or more surfaces of the metallic film.

In another embodiment, the at least one of the centers is disposed within approximately 500 nm or less of at least one of the nanofeatures.

In yet another embodiment, the surface plasmon wavelength converter device further includes a support layer adjacent to a selected one of the metallic film and the wavelength conversion layer.

In yet another embodiment, the thickness of the metallic film is configured to allow coupling between a plasmon wave on the metallic film first surface and a plasmon wave on the metallic film second surface.

In yet another embodiment, the thickness of the metallic film is less than about ten skin depths at the first wavelength.

In yet another embodiment, the at least one of the plurality of nanofeatures has a dielectric constant different than a dielectric constant of the metallic film.

In yet another embodiment, the at least one of the plurality of nanofeatures includes a metal of different composition than a metal of the metallic film.

In yet another embodiment, the at least one of the plurality of nanofeatures includes a dielectric material.

In yet another embodiment, the at least one of the plurality of nanofeatures has a diameter in a range of approximately 10 nm to 10,000 nm.

In yet another embodiment, the plurality of nanofeatures is configured in an array having a spacing between nearest neighbors of the plurality of nanofeatures in a range of about 10 nm to 10,000 nm.

In yet another embodiment, the metallic film includes a metal selected from the group of metals consisting of silver, gold, copper, and aluminum.

In yet another embodiment, the wavelength conversion layer includes a lanthanide dopant.

In yet another embodiment, the lanthanide dopant includes a selected one of erbium, ytterbium, praseodymium, europium, cerium, and thulium.

In yet another embodiment, an integrated solar cell, includes a surface plasmon wavelength converter device having at least one solar cell layer optically coupled thereto. A first positive electrical terminal and a second negative terminal are configured to provide an electrical current and an electrical voltage as output signals.

In yet another embodiment, the integrated solar cell further includes at least one additional second surface plasmon wavelength converter device. The additional second surface plasmon wavelength converter device is optically coupled to the solar cell.

In yet another embodiment, a material is configured to exhibit optical transparency within a selected wavelength range. The material is configured to encapsulate the solar cell system.

In another aspect, the invention relates to a surface plasmon wavelength converter device which includes a metallic film having a plurality of nanofeatures. The metallic film has a metallic film first surface and a metallic film second surface. At least one center is disposed in at least one of the plurality of nanofeatures. The surface plasmon wavelength converter device is configured to respond to an incident electromagnetic radiation having a first wavelength by radiating away from the surface plasmon wavelength converter device an electromagnetic radiation having a second wavelength.

In one embodiment, the at least one of the centers is disposed within approximately 500 nm or less of at least one of the nanofeatures.

In another embodiment, the nanofeatures are configured to exhibit intensified fields in response to the surface plasmon waves generated at one or more surfaces of the metallic film.

In yet another embodiment, the surface plasmon wavelength converter device further includes a support layer adjacent a selected one of the metallic film and the wavelength conversion layer.

In yet another embodiment, a thickness of the metallic film is configured to allow coupling between a plasmon wave on the metallic film first surface and a plasmon wave on the metallic film second surface.

In yet another embodiment, the thickness of the metallic film is less than about ten skin depths at the first wavelength.

In yet another embodiment, the at least one of the plurality of nanofeatures has a dielectric constant different than a dielectric constant of the metallic film.

In yet another embodiment, the at least one of the plurality of nanofeatures includes a metal of different composition than a metal of the metallic film.

In yet another embodiment, the at least one of the plurality of nanofeatures includes a dielectric material.

In yet another embodiment, the at least one of the plurality of nanofeatures has a diameter in a range of approximately 10 nm to 10000 nm.

In yet another embodiment, the plurality of nanofeatures is configured in an array having a spacing between nearest neighbors of the plurality of nanofeatures in a range of approximately 10 nm to 10000 nm.

In yet another embodiment, the metallic film includes a metal selected from the group of metals consisting of silver, gold, and aluminum.

In yet another embodiment, the wavelength conversion layer includes a lanthanide dopant.

In yet another embodiment, the lanthanide dopant includes a selected one of erbium, ytterbium, praseodymium, europium, cerium, and thulium.

In yet another embodiment, an integrated solar cell includes a surface plasmon wavelength converter device having at least one solar cell layer optically coupled thereto. A first positive electrical terminal and a second negative terminal are configured to provide an electrical current and an electrical voltage as output signals.

In yet another embodiment, the integrated solar cell further includes at least one additional second surface plasmon wavelength converter device the additional second surface plasmon wavelength converter device.

In yet another embodiment, a material is configured to exhibit optical transparency within a selected wavelength range. The material is configured to encapsulate the solar cell system.

In yet another aspect, the invention relates a surface plasmon wavelength converter device which includes a transparent conductive oxide (TCO) film having a plurality of metallic nanofeatures. The TCO film has a TCO film first surface and a TCO film second surface. A wavelength conversion layer having a plurality of centers is disposed adjacent to and optically coupled to the first surface of the TCO film. The surface plasmon wavelength converter device is configured to respond to an incident electromagnetic radiation having a first wavelength by radiating away from the surface plasmon wavelength converter device an electromagnetic radiation having a second wavelength.

In yet another aspect, a surface plasmon wavelength converter device includes a transparent conductive oxide (TCO) film which has a plurality of metallic nanofeatures. The TCO film has a TCO film first surface and a TCO film second surface. At least one center is disposed in at least one of the plurality of metallic nanofeatures. The surface plasmon wavelength converter device is configured to respond to an incident electromagnetic radiation having a first wavelength by radiating away from the surface plasmon wavelength converter device an electromagnetic radiation having a second wavelength.

The foregoing and other objects, aspects, features, and advantages of the invention will become more apparent from the following description and from the claims.

### BRIEF DESCRIPTION OF THE DRAWINGS

For a further understanding of these and objects of the invention, reference will be made to the following Detailed Description, which is to be read in connection with the accompanying drawings, where:

FIG. 1 shows an illustration of a prior art solar cell.

FIG. 2 shows an illustration of one exemplary embodiment a surface plasmon wavelength converter structure according to the invention.

FIG. 3 shows an illustration of a surface plasmon wavelength converter having a single nanofeature layer.

FIG. 4 shows an illustration of a surface plasmon wavelength converter having a single wavelength converter layer.

FIG. 5 shows an illustration of a surface plasmon wavelength converter device structure which uses a tunneling surface plasmon wave to improve emission efficiency.

FIG. 6 shows an illustration of a surface plasmon wavelength converter structure having a nanofeature layer on both sides of a wavelength converting layer.

FIG. 7 shows an illustration of an array of nanofeatures at an interface between a first dielectric layer and an optional second dielectric layer.

FIG. 8A shows an illustration of a plane view of a nanofeature layer formed in a metal sheet.

FIG. 8B shows an illustration of a cross section view of the metal sheet of FIG. 8A.

FIG. 9 shows an illustration of a surface plasmon wavelength converter structure having multiple upconversion or downconversion wavelength converting layers.

FIG. 10 shows an illustration of one exemplary embodiment of an amorphous silicon integrated solar cell according to the invention.

FIG. 11 shows an illustration of another exemplary embodiment of an integrated solar cell having multiple stacked layers.

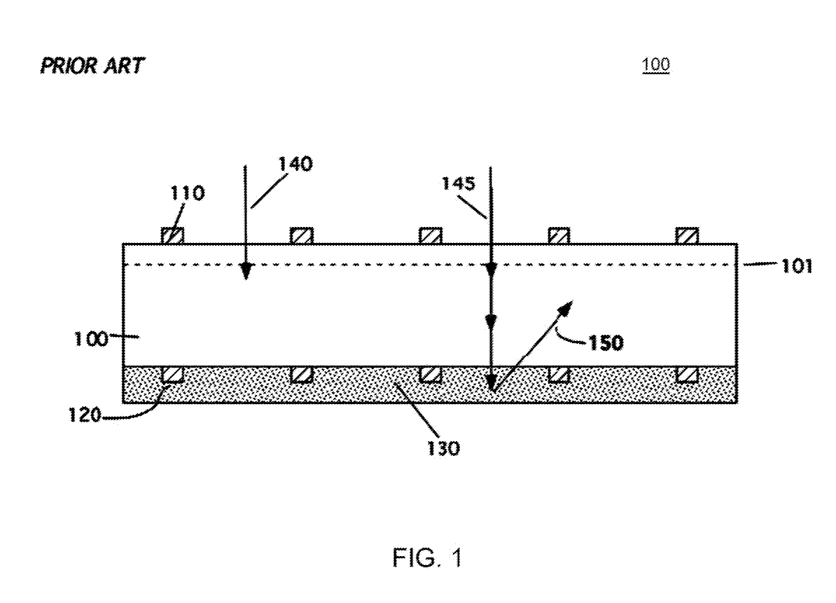

The drawings are not necessarily to scale, emphasis instead generally being placed upon illustrating the principles of the invention. In the drawings, like numerals are used to indicate like parts throughout the various views.

### DETAILED DESCRIPTION

### Definitions

“Nanofeatures” are defined as (i) one or more types made of metallic nanoscale structures or particles typically embedded in a dielectric (including a solid dielectric, liquid dielectric, air, dielectric gas, or vacuum), insulator, semiconductor, polymer, or other material having a different dielectric coefficient than the metallic nanoscale structures or particles such as an oxide film, and (ii) one or more type of non-metallic nanoscale particles or structures made of a dielectric material (including a solid dielectric, liquid dielectric, air, dielectric gas, or vacuum), semiconductor, insulator, polymer or other material typically embedded in a metallic material having a different dielectric coefficient than the non-metallic nanoscale particles materials.

“Nanofeature layer” is defined as (i) layers of nanofeatures, and (ii) layers of metals or other conductive media that have an array of nanoscale voids, depressions, protrusions, or other nanoscale patterns.

“Nanofeature array” is defined as a nanofeature layer having a repeated pattern of nanoscale features. A nanofeature array can also include any suitable combination of features, such as for example, a metallic layer such as a metallic film having two or more types of dielectric nanofeatures. A nanofeature array can also include a dielectric layer with a plurality of patterns of metallic nanofeatures, or other nanoscale features in any suitable combination. A nanofeature array typically has one or more periodic patterns of nanofeatures.

A “center” is defined as a molecule, atom, ion, or combination that absorbs at one wavelength and emits at a second wavelength, e.g. a molecule comprising one or more rare earth ions, other atoms, and nanofeatures; a crystal such as a quantum dot; or any aggregation of atoms which can act as a wavelength converter. Suitable exemplary molecules include fluorescent or phosphorescent molecules. Exemplary rare earth ions are ions of erbium, ytterbium, praseodymium, europium, cerium, and thulium. Centers are associated with a wavelength conversion of electromagnetic radiation, e.g. a wavelength conversion of incident photons. A wavelength conversion can be an upconversion or a downconversion. Typically, one or more centers are disposed in or on a wavelength conversion layer.

A “support layer” is a layer upon which another layer or structure is stacked in an integrated structure, such as for example, an integrated solar cell structure. A support layer can be a passive layer present for purposes of physical support, such as a substrate of any suitable type or a device coating or cover (e.g. a glass surface). A support layer can also be any suitable adjacent active layer.

### Exemplary Embodiments of the Invention

A new wavelength conversion technique and device, a surface plasmon wavelength converter device which can perform wavelength conversion with increased emission efficiency and can be manufactured at relatively low cost is now described. As described by Catchpole, et al., metallic nanoparticles have plasmon modes that depend on material conductivity, physical shape, and physical size. By adjusting material conductivity, physical shape, and/or physical size according to the invention, and as described in more detail herein, it has been realized that metallic nanoparticles can be adapted to affect the fields near wavelength converter materials (e.g. centers) and thereby change the radiative lifetime thus improving device efficiency. Metallic nanoparticles thus used can modify the plasmon spectra in order to tune the resonant frequency to the transition wavelength in an upconversion or downconversion layers.

Surface plasmon wavelength converter devices according to the invention convert an incident electromagnetic radiation (typically photons of light) at a first wavelength to an emitted electromagnetic radiation (also typically photons of light) at a second wavelength. Such devices can also be configured to emit electromagnetic radiation at the second wavelength in a particular direction. Surface plasmon wavelength converter devices, as described hereinbelow in more detail, typically have at least one metallic film layer with nanofeatures. The nanofeatures have a dielectric constant different than the material of the metal film. In other embodiments including any of the embodiments described hereinbelow; a transparent conductive oxide (TCO) film having metallic nanofeatures can replace the metallic film. One common aspect of the surface plasmon wavelength converter device embodiments described herein is an increase in emission efficiency of one or more wavelength converter layers or an increase of emission efficiency of converters disposed within nanofeatures of a nanofeature layer. The nanofeatures in a metallic film or in a TCO film can be disposed in an array (i.e. a periodic pattern of a nanoarray), or in a pseudo random, or a random pattern, or any combination thereof.

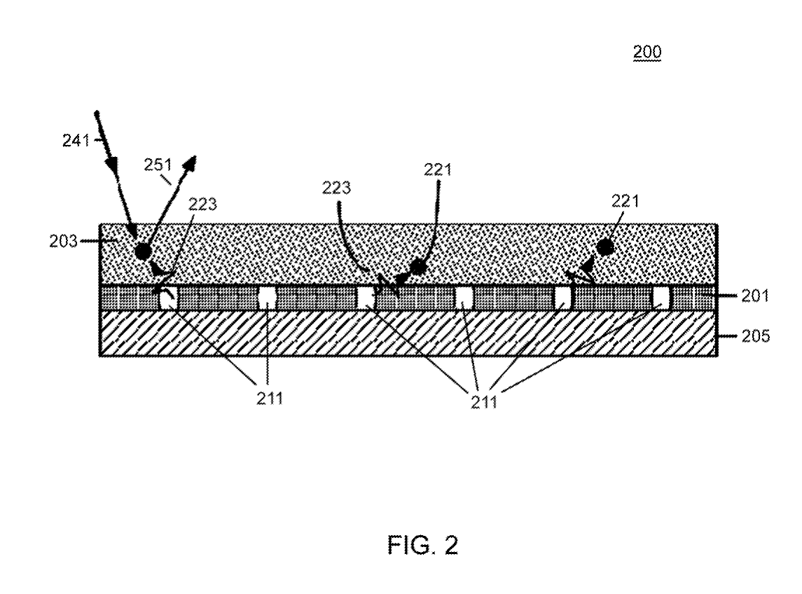

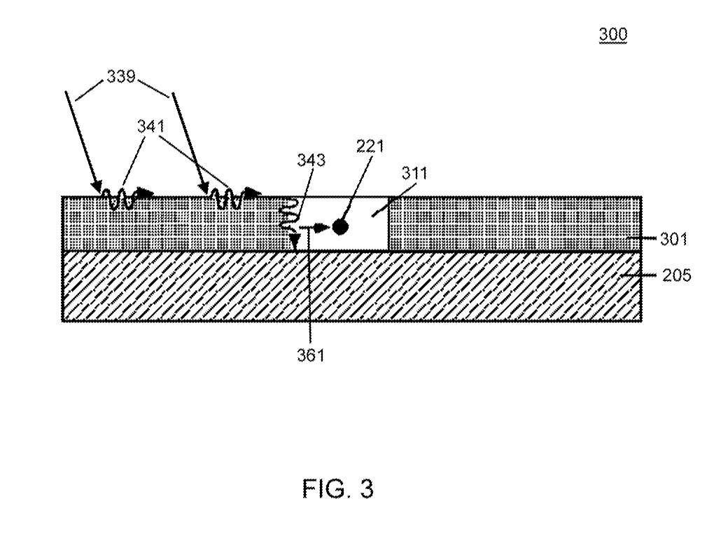

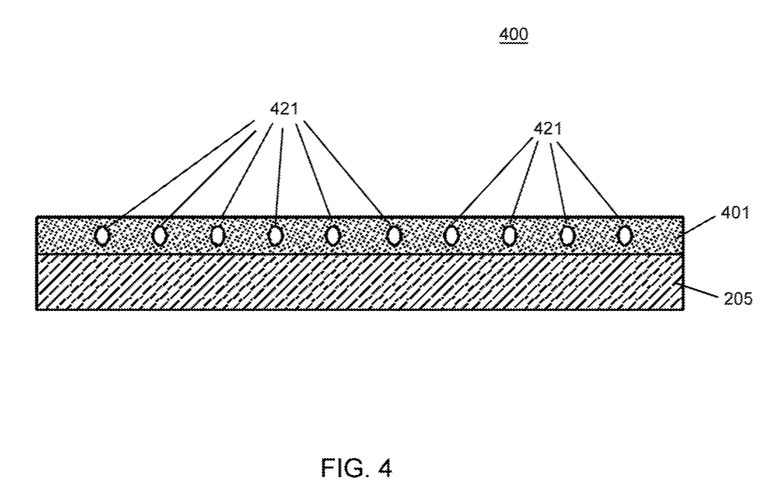

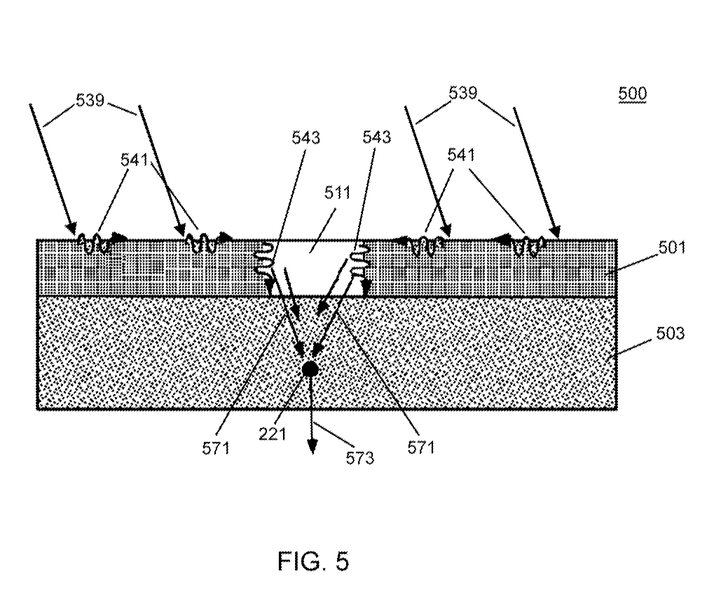

FIG. 2, FIG. 3, FIG. 4 and FIG. 5, show exemplary embodiments of surface plasmon wavelength converter device structures according to the invention. FIG. 2 shows an illustration of a surface plasmon wavelength converter device that uses a nanofeature (plasmonic) layer to influence the field and radiative rate of a wavelength conversion layer. FIG. 3 shows an illustration of a surface plasmon wavelength converter device based on a nanofeature layer which combines the functions of wavelength conversion and emission efficiency enhancement by including centers within the nanofeatures of the nanofeature layer. FIG. 4 shows an illustration of a surface plasmon wavelength converter device based on a wavelength conversion layer which combines the functions of wavelength conversion and emission efficiency enhancement by including nanofeatures within the wavelength conversion layer. FIG. 5 shows an illustration of an embodiment of a surface plasmon wavelength converter device structure which uses a tunneling surface plasmon wave to improve emission efficiency. These and other exemplary embodiments are now described in more detail hereinbelow.

FIG. 2 shows an illustration of one exemplary embodiment of a surface plasmon wavelength converter structure 200 according to the invention. A second surface of nanofeature layer 201 (a plasmonic layer) is disposed on a support layer 205, such as for example, a substrate. Nanofeature layer 201 includes a plurality of nanofeatures 211. A wavelength conversion layer 203 (upconverting or downconverting) is disposed adjacent to a first surface of nanofeature layer 201 (a plasmonic layer). Wavelength conversion layer 203 includes a plurality of centers 221. Wavelength conversion layer 203 can be made of a material which suspends centers 221. For example, wavelength conversion layer 203 can be made of a material which suspends centers 221 in a matrix. Such materials include, bonding materials, such as for example, polymers, such as ethylene vinyl acetate, and other suitable adhesives which can support a matrix of centers 221.

Turning now to the operation of the surface plasmon wavelength converter structure 200 of FIG. 2, Incident electromagnetic radiation, such as photons 241, excite transition states at centers 221 disposed within the wavelength conversion layer 203. The excited transition states of centers 221 can be associated, for example, with lanthanide dopants such as erbium at or in the immediate vicinity of centers 221. The nanoscale features 211 of nanofeature layer 201 are configured to tune a resonance frequency of nanofeature layer 201 to a desired transition frequency of centers 221. Fields 223 from the nanoscale features 211 extend to centers 221. Analogous to the Purcell Effect, fields 223 increase the transition probability of radiative recombination, thus leading to an enhanced rate of emission of photons 251. It is believed that in the embodiment of FIG. 2, plasmon waves associated with nanoscale features 211 influence the photon transitions at centers 221 and the fields in the vicinity of centers 221 and the radiative rate. The emission of photons 251 by wavelength conversion layer 203 is thus enhanced as compared with a wavelength conversion layer 203 not disposed adjacent to a plasmonic layer (e.g. a nanofeature layer 201) which is suitably tuned in wavelength.

FIG. 3 shows an illustration of an exemplary embodiment of a surface plasmon wavelength converter 300 having a single nanofeature layer 301 including nanofeatures 311 with centers 221. Nanofeature layer 301 (typically a metallic film) is disposed on a support layer 205. Here, centers 221 (upconverting or downconverting) are disposed within the nanofeatures 311. Nanofeature layer 301 can be made of any suitable conductor, such as for example, silver, gold, copper, or aluminum and nanofeatures 311 can be present as a dielectric material, such as for example, air or silicon dioxide.

In the embodiment of FIG. 3, wavelength conversion takes place in the nanofeature layer 301 and nanofeatures 311. Therefore, in the embodiment of FIG. 3, a separate wavelength conversion layer (e.g. layer 203 of FIG. 2) is not needed. Photons, such as those received from incident light 339 excite surface plasmons 341 which induces surface plasmon waves 343 and cause them to travel along the surface of nanostructure layer 300. Surface plasmon waves 343 are collective oscillation of surface plasmons 341. It is believed that at resonance, photons and surface plasmon waves 343 concentrate at sides of nanofeatures and therefore create a highly intense field 361 in nanofeatures 311. Therefore, it can be seen that by placing centers 221 in or near (as in the cases of FIG. 2 and FIG. 5) the nanofeatures 311, wavelength conversion processes can be enhanced due to the high optical flux associated with such concentrated light (e.g. multiple photons) and fields in nanofeatures 311. In some embodiments of FIG. 3, nanofeatures 311 are tuned to be resonant with a wavelength or range of wavelengths of the incident light 339.

Just as a surface plasmon wavelength converter structure can be made from a single nanofeature layer having centers disposed in nanofeature layer (FIG. 3), a surface plasmon wavelength converter structure can also be made from a single wavelength converter layer having nanofeatures disposed within. FIG. 4 shows an illustration of one such exemplary embodiment of a surface plasmon wavelength converter structure 400 having a single wavelength converter layer 401 with nanofeatures 421. An upconverting or downconverting wavelength converting layer 401 is disposed on a support layer 205 and an array of nanofeatures 421 are formed within wavelength converting layer 401. In this case surface plasmon fields (not shown) at the surface of nanofeatures 421 couple to centers 221 (not shown in FIG. 4), e.g. excited ions, in wavelength converting layer 401, thus reducing the radiative lifetime and thereby improving the emission efficiency of the device. In some cases, nanofeatures (e.g. nanofeatures 421) can also be the centers 221.

FIG. 5 shows an illustration of another exemplary embodiment of a surface plasmon wavelength converter structure 500. A nanofeature layer 501 (typically a metallic film) includes a plurality of nanofeatures 511. Nanofeature layer 501 is disposed adjacent to a wavelength conversion layer 503 having a plurality of centers 221. Incident light 539 excites surface plasmons 541 on nanofeature layer 501. Surface plasmons 541 act collectively within nanofeatures 511, by tunneling as surface plasmons 543, and re-radiate light as photons 571. Photons 571 are localized near the nanofeatures 511 and thus the field strengths near the nanofeatures 511 are highly concentrated. Centers 221 situated near nanofeature 511 each receive the benefit of the concentrated light 571. Wavelength converted light 573 is emitted from centers 221. A structure 500 can give similar benefits for either non-linear upconversion or downconversion processes which either convert or emit multiple photons.

In the embodiments of FIG. 3 and FIG. 5, the thickness of the nanofeature layer 301 and nanofeature layer 501 should be chosen so that surface plasmons 343 and surface plasmons 543 respectively can propagate along nanofeatures 311 and 511 respectively. Typically such nanofeature layers can be made using a thin film, such as a metal thin film. The thickness of such nanofeature layers can be selected to be thin enough so that surface plasmon waves on the first and second surfaces of the nanofeature layer can couple together and energy can tunnel through the nanofeature layer and intensify the fields at the nanofeatures. These intensified fields can be used to excite centers 221. As described hereinabove, such centers 221 can be disposed within nanofeatures (e.g. centers 221 disposed in nanofeatures 311, FIG. 3) or adjacent to the nanofeatures (e.g. centers 221 in a wavelength conversion layer 503 adjacent to nanofeatures 511, FIG. 5). Note that there here is a trade off in thickness of the nanofeature layer. If the nanofeature layer is too thin, photons can propagate through the layer without interacting with surface plasmons. If the nanofeature layer is too thick, less energy can tunnel through the nanofeatures. It is believed that generally two to three skin depths at wavelengths of interest provide a near optimal thickness for such nanofeature layers. It is also believed that a nanofeature thicknesses ranging from about less than one skin depth to about ten to twenty skin depths can still have some useful tunneling effects.

Nanofeatures and nanofeature layers are typically tuned to be resonant with either an input or received wavelength or a converted (output) wavelength of centers 221. However, it should be noted that in other embodiments, such as some of those described hereinbelow, there can also be multiple nanofeature layers where one layer is tuned to be resonant with an incident electromagnetic radiation at a received wavelength and another nanofeature layer can be tuned to be resonant with a re-emitted electromagnetic radiation at a converted wavelength different than the received wavelength. Or, there can be nanofeature layers having two or more types of nanofeatures which can thus be tuned simultaneously to two or more wavelengths.

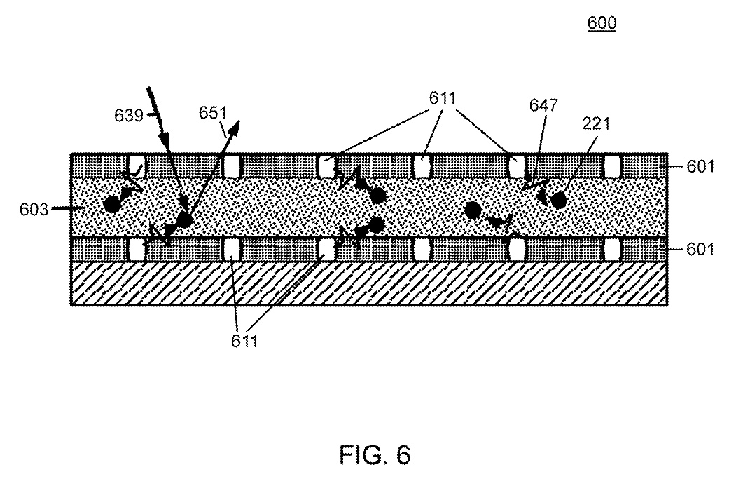

FIG. 6 shows an illustration of another exemplary embodiment of a surface plasmon wavelength converter structure 600. Here, resonant structures such as nanofeature layers 601 (typically metallic films) having nanofeatures 611, can be placed on both sides of a wavelength converting layer 603. This approach allows the thickness of layer 603 to be increased while maintaining the effect of the resonance. Incident electromagnetic radiation 639 (typically photons of light) cause plasmonic waves 647, which interact at centers 221, to emit electromagnetic radiation 651 (also, typically photons of light) at a different wavelength than the wavelength of incident electromagnetic radiation 639. Note that any number of laminae (successive layers of nanofeature layers 601 and wavelength converting layers 603) can be used to increase the total aggregate thickness of structure 600, while maintaining transition states of centers 221 within range of a nanofeature layer 601.

### Wavelength Converter Layers:

Wavelength conversion efficiency (e.g. upconversion or downconversion) can be limited by two factors. One factor is the density of upconverting centers. For example, in the case of Er-doped NaYF4, the upconversion centers are Er ions that can be doped as high as a few percent. The Er ions retain photo-excited electrons for a characteristic “lifetime,” followed by decay of the excited state. Thus each ion can upconvert on average at the characteristic rate, and for this reason the process can become saturated. If the lifetime can be decreased, this rate can be increased, meaning that a greater number of photons can be emitted per second by each ion without saturation.

Another factor affecting upconversion and downconversion efficiency is non-radiative recombination. In a non-radiative recombination process, the excited electron returns to the ground state by creation of phonons (heat) instead of re-radiating a photon. Non-radiative recombination processes also occur at a characteristic rate. Therefore, if the radiative recombination rate can be increased, not only will the upconverter have higher throughput but also a greater fraction of the output will be radiative.

Also, regarding radiative lifetimes, the radiative lifetime in lanthanide ions is a function of atomic transition probability. This probability is highly influenced by local electric fields. Stimulated emission is an example of a local field changing the transition probability. For example, in the Purcell Effect a resonant cavity is used to enhance the transition probability of an excited atom by augmenting the local field. Surface plasmon resonances can also change the local fields and can form an analog of the resonant cavity.

### Nanofeature Array Layers:

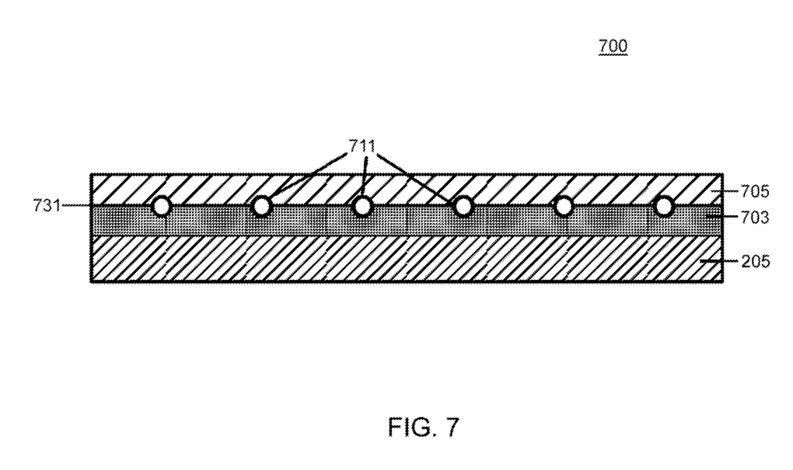

FIG. 7 shows an illustration of a structure 700 having an array of nanofeatures 711 at an interface 731 between a first dielectric layer 703 and an optional second dielectric layer 705. The first dielectric layer 703 can be placed on a support layer 205 which can be made, for example, from a metal, an insulator, or a semiconductor. The first dielectric layer 703 and the second dielectric layer 705 can be made of the same material. The nanofeatures 711 can be made from, for example, metallic silver or other metals typically having a diameter between about 10 and 10,000 nm with a spacing of about 10 to 10,000 nm. Nanofeatures 711 have resonant modes that can be tuned by adjusting the size, shape and spacing of the nanofeatures. While spherical nanofeatures are shown in FIG. 7, such nanofeatures 711 can also have the shape or shapes of cylinders, cubes, tetrahedrons and/or any other suitable shapes.

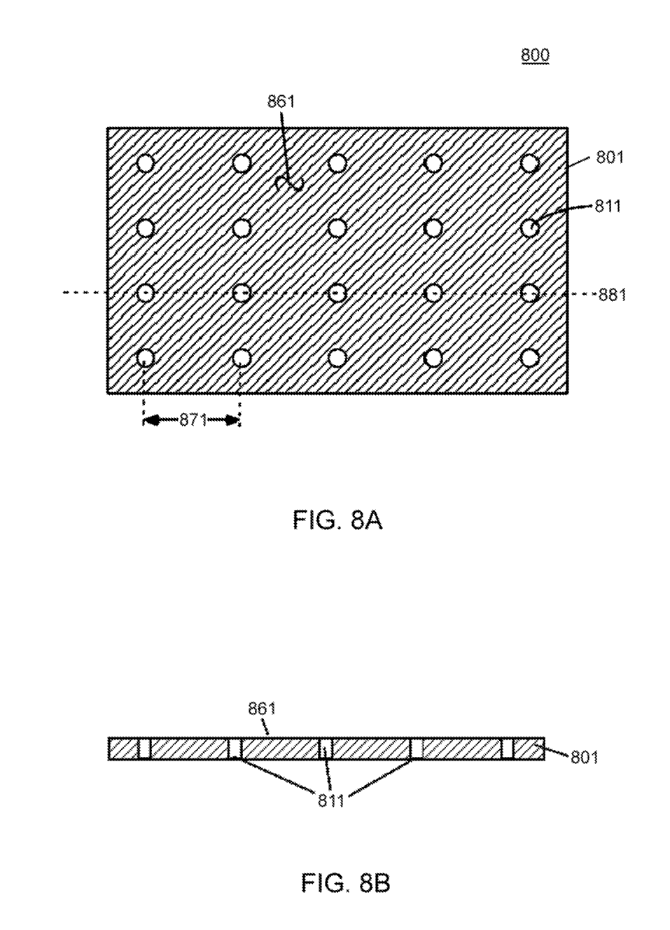

FIG. 8A shows an illustration of a plane view of a nanofeature layer 800 formed in a metal sheet such as a metal film 801 having a thickness of about 10 to 200 nm. The surface plasmons (not shown) that travel at the surface 861 of the metal have resonant frequencies that depend on the spacing 871 and size of the nanofeatures 811 which can be, for example, protrusions, voids, or depressions. In such a case, the surface plasmon resonant frequencies are affected by the presence of the nanofeatures 811. FIG. 8B shows an illustration of a cross section view of metal film 801 taken at line 881 (FIG. 8A). The nanoscale features 811 of metal film 801 (a nanofeature layer) can be filled with any suitable solid, liquid or gas, or a vacuum. The boundary of each nanofeature 811, e.g. nanofeatures or vias and its host material (e.g. metal film 801) can be delineated by a change in conductivity of at least one order of magnitude.

As described hereinabove, the surface plasmon resonant frequencies can be affected by the presence of nanoscale features. For a periodic structure such as periodic array of apertures, this resonant condition can be described as:

$$λ = {a}_{0} \sqrt{\frac{{ɛ}_{1} {ɛ}_{2}}{{ɛ}_{1} + {ɛ}_{2}}} \qquad ( 1 )$$

where λ is the wavelength of the incident electromagnetic radiation; a₀ is the lattice constant; ∈₁ and ∈₂ are real portions of the respective dielectric constants for the metallic substrate and the surrounding medium in which the incident radiation passes prior to irradiating the metal film. For a non-periodic structure, the above equation can be modified to describe the resonant condition for a non-periodic structure. For example, where a configuration comprises a single aperture at the center of a single annular groove, the resonant condition may be described as:

$$λ = ρ \sqrt{\frac{{ɛ}_{1} {ɛ}_{2}}{{ɛ}_{1} + {ɛ}_{2}}} \qquad ( 2 )$$

where ρ denotes the radius of the annular groove from the centrally positioned aperture within the annular groove.

### Upconversion and Downconversion of Multiple Wavelengths:

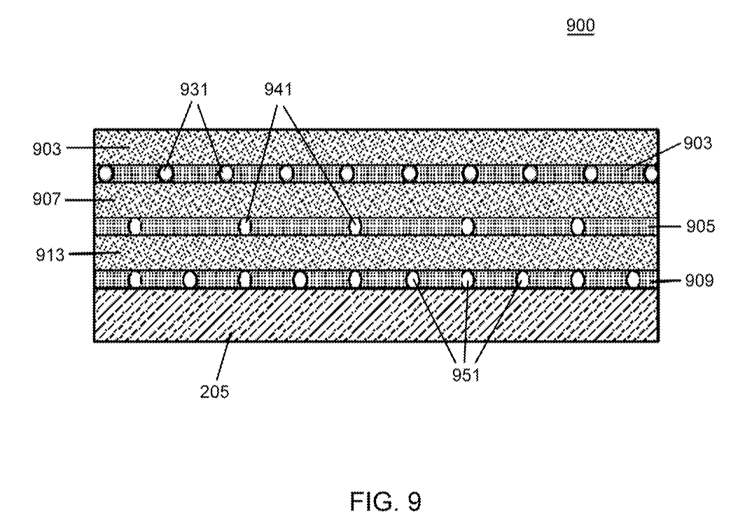

Upconversion and downconversion of multiple wavelengths can be accomplished by multilayer integrated structures. FIG. 9, for example, shows an illustration of an embodiment of a surface plasmon wavelength converter structure 900 disposed on a support layer 205. Surface plasmon wavelength converter structure 900 can provide both upconversion and downconversion of multiple wavelengths. Multiple upconversion or downconversion wavelength converting layers 903, 907, and 913 having centers 221 (not shown in FIG. 9) are interleaved with nanoarray layers 903, 905, and 909 having respectively nanofeatures 931, 941 and 951. Each of the wavelength converting layers and the nanoarray layers can have different transition wavelengths. With each nanoarray layer respectively tuned to a particular transition in the corresponding layer, the radiative lifetime of centers having multiple wavelengths is reduced.

### Stacking:

As described herein and illustrated by numerous exemplary embodiments, surface plasmon wavelength converter device structures can be made from single or multiple layers. Any of the surface plasmon wavelength converter device structures described herein can be stacked in integrated surface plasmon wavelength converter device structures. Such stacking can be done to further increase efficiency of a single wavelength conversion and/or to implement multiple wavelength conversions in a single device. Note also that multiple wavelength conversions can be accomplished successively in a single direction, such as multiple wavelength upconversions or multiple wavelength downconversions. As is described hereinbelow in more detail, one or more solar cell or photovoltaic layers can be included in such stacks to make more efficient integrated solar cells.

### Direction of Emitted Electromagnetic Radiation:

Another aspect of a surface plasmon wavelength converter device is the ability to direct electromagnetic radiation emitted a second wavelength in a particular direction. For example, a nanopattern, such as a nanoarray can be configured to direct an emitted light so that it can be more efficiently captured or absorbed within an adjacent layer, such as an adjacent solar cell or photovoltaic layer.

### Solar Cell Applications:

Any of the surface plasmon wavelength converter structures described hereinabove can be combined with one or more solar cell or photovoltaic layers to create a more efficient integrated solar cell structure. For example, a surface plasmon wavelength converter structure 200 (FIG. 2) can be can be disposed adjacent to a solar cell. In one such exemplary embodiment, support layer 205 can be a substantially optically transparent material, such as a glass material and wavelength conversion layer 203 can be placed against an illumination receiving surface of a solar cell (typically referred to as a “front surface” of the solar cell). In some such embodiments, support layer 205 also can also serve to encapsulate the integrated solar cell. Alternately, a surface plasmon wavelength converter (e.g. a structure 200) can be placed adjacent to a surface of a solar cell opposite the front surface (e.g. at the “back side” or “back surface” of a solar cell or photovoltaic conversion layer).

Also, more complex integrated layers of plasmonic nanofeature layers and upconverting or downconverting layers (e.g. the multiple wavelength converting layers of FIG. 9) can be integrally formed with a solar cell as part of the manufacturing process or one or more plasmonic nanofeature layers can be added between the glass and any suitable solar cell or other types of photovoltaic devices during a module manufacturing process. Suitable methods for forming nanoscale features described herein include electron beam lithography followed by metal deposition, spin-on processes in which the nanofeatures are suspended in a colloidal or other solution, or by nano-imprinting.

Integrated solar cell structures include at least a positive electrical terminal and a negative electrical terminal for supplying an electrical current generated by the incident electromagnetic radiation (typically photons of light).

### Manufacturing Processes:

Dennis Slafer of the MicroContinuum Corporation of Cambridge, Mass., has described several manufacturing techniques and methods that are believed to be suitable for the manufacture of surface plasmon wavelength converter devices as described herein. For example, U.S. patent application Ser. No. 12/358,964, ROLL-TO-ROLL PATTERNING OF TRANSPARENT AND METALLIC LAYERS, filed Jan. 23, 2009, describes and teaches one exemplary manufacturing process to create metallic films having a plurality of nanofeatures suitable for use in surface plasmon wavelength converter devices as described herein. Also, U.S. patent application Ser. No. 12/270,650, METHODS AND SYSTEMS FOR FORMING FLEXIBLE MULTILAYER STRUCTURES, filed Nov. 13, 2008, U.S. patent application Ser. No. 11/814,175, Replication Tools and Related Fabrication Methods and Apparatus, filed Aug. 4, 2008, U.S. patent application Ser. No. 12/359,559, VACUUM COATING TECHNIQUES, filed Jan. 26, 2009, and PCT Application No. PCT/US2006/023804, SYSTEMS AND METHODS FOR ROLL-TO-ROLL PATTERNING, filed Jun. 20, 2006 describe and teach related manufacturing methods which are also believed to be useful for manufacturing surface plasmon wavelength converter devices as described herein. Each of the above identified United States and PCT applications is incorporated herein by reference in its entirety for all purposes.

Also, it is noted that a “via” is believed to be one exemplary integrated structure which can be used to make suitable nanofeatures in a metallic film or TCO film layer. Vias can be created in an integrated layer using any suitable lithography or nanoprinting manufacturing process.

### EXAMPLE

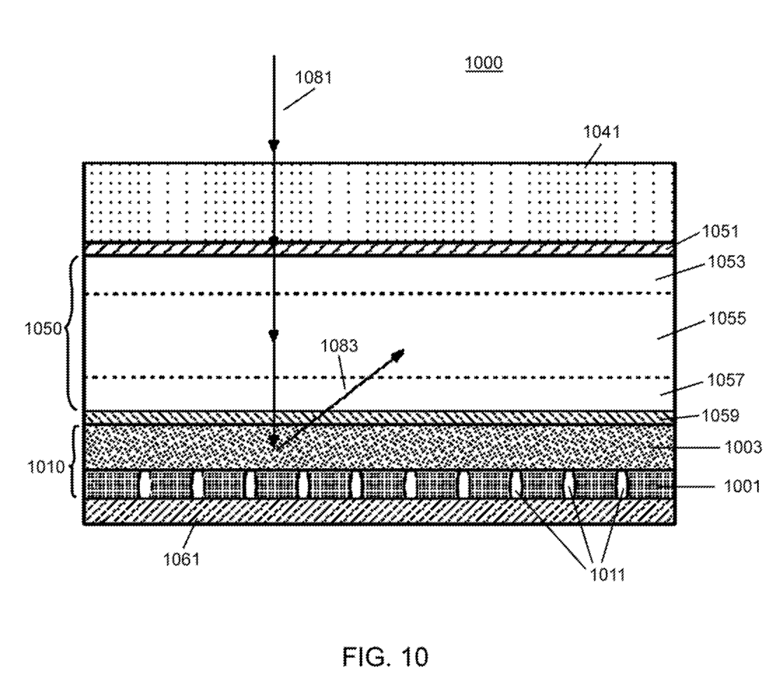

FIG. 10 shows an illustration of an exemplary amorphous silicon integrated solar cell 1000 according to the invention. Solar cell 1000 is formed on a glass layer 1041 upon which is deposited a transparent conductive oxide such as an indium tin oxide coating 1051. An amorphous silicon cell 1050 comprising a p-type layer 1053, intrinsic layer 1055 and an n-type layer 1057 is deposited by plasma enhanced chemical vapor deposition. A diffusion barrier 1059, made of a material such as ZnO, can be used to protect the amorphous silicon from the subsequent layer depositions. A surface plasmon wavelength converter 1010 includes a wavelength conversion layer 1003, made from a material such as erbium doped NaYF4, deposited on the diffusion barrier 1059. A nanofeature layer 1001 (a nanoarray) comprising a metal film with nanoscale features 1011 is formed on the wavelength conversion layer 1003. The nanofeature layer 1001 can be formed, for example, by creating a lift-off mask that is patterned preferably by non-imprinting, but can alternatively be patterned by electron beam lithography or other suitable means. A metal layer is deposited by physical vapor deposition, and lifted off, or alternatively, the nanoarray metal can be removed by etching. A back contact 1061 is then applied. Alternatively, an additional conductive layer, made of a material such as ZnO, can be added to separate the nanofeature layer from the back contact.

Turning now to the operation of solar cell 1000, incident electromagnetic radiation 1081 (typically photons of light represented by light rays) characterized by an energy of less than 1.7 eV (nominally the band gap) typically passes through the amorphous silicon (without being absorbed) and excites centers in the wavelength conversion layer 1003. The nanofeature layer 1001 provides fields that increase the probability of radiative recombination. Centers (not shown in FIG. 10) radiate upconverted electromagnetic radiation 1083 (here photons of light) which now can be absorbed by the amorphous silicon solar cell 1050, thereby increasing its short circuit current and conversion efficiency.

### EXAMPLE

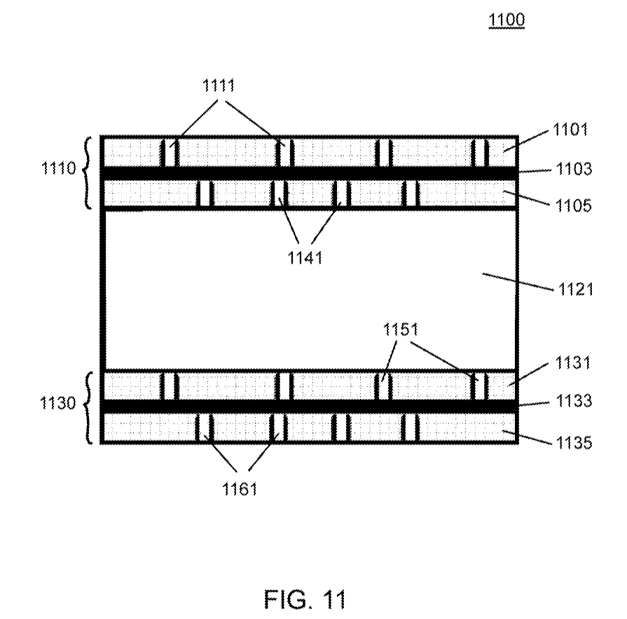

FIG. 11 shows an illustration of another exemplary embodiment of an integrated solar cell 1100 using stacked layers. Integrated solar cell 1100 includes surface plasmon wavelength converter structure 1110 and surface plasmon wavelength converter structure 1130. Surface plasmon wavelength converter structure 1110 includes a nanofeature layer 1101 having nanofeatures 1111, wavelength conversion layer 1103, and nanofeature layer 1105 having nanofeatures 1141. Surface plasmon wavelength converter structure 1130 includes a nanofeature layer 1131 having nanofeatures 1151, wavelength conversion layer 1133, and nanofeature layer 1135 having nanofeatures 1161. As described hereinabove, nanofeatures 1111, 1141, 1151, and 1161 can include any suitable nanohole pattern including positive and negative patterns such as, triangle, stars, posts, etc. Surface plasmon wavelength converter structure 1110 serves as a downconversion layer at a first surface (e.g. nearer to the front surface of solar cell 1100) and surface plasmon wavelength converter structure 1130 serves as an upconversion layer at on an opposite second surface (e.g. nearer to a back surface of solar cell 1100). The position of these layers can be reversed. The nanofeature layers can be both tuned to increase absorption of photons by converters, and to improve radiative rate to improve total upconversion or downconversion of the photons by converters.

Surface plasmon wavelength converter structure 1110 is now described in more detail. In some embodiments, nanofeature layer 1101 can be used to absorb and enhance electric and/or magnetic fields of an incident electromagnetic radiation (typically photons of light) and nanofeature layer 1105 can be tuned to control the emission environment to improve the radiative rate. Both nanofeature layer 1101 and nanofeature layer 1105 can therefore improve the conversion efficiency of integrated solar cell 1100. Surface plasmon wavelength converter structure 1130 can have similar operation, here acting as an upconverting surface plasmon wavelength converter structure.

Note that although multiple layers of nanopattern and wavelength shifting can perform better than single layer embodiments (e.g. higher integrated solar cell efficiency) there is no need for multiple layers. As described with regard to the many embodiments of surface plasmon wavelength converter devices structures described hereinabove, integrated solar cells can include one or more sets of nanopattern and/or wavelength shifting layers.

Although the theoretical description given herein is thought to be correct, the operation of the devices described and claimed herein does not depend upon the accuracy or validity of the theoretical description. That is, later theoretical developments that may explain the observed results on a basis different from the theory presented herein will not detract from the inventions described herein.

While the present invention has been particularly shown and described with reference to the preferred mode as illustrated in the drawing, it will be understood by one skilled in the art that various changes in detail may be affected therein without departing from the spirit and scope of the invention as defined by the claims.

What is claimed is:

1. A surface plasmon wavelength converter device, comprising:
a metallic film having a plurality of nanofeatures, said metallic film having a metallic film first surface and a metallic film second surface; and
a wavelength conversion layer having a plurality of centers, said wavelength conversion layer disposed adjacent to and optically coupled to said first surface of said metallic film,
wherein said surface plasmon wavelength converter device is configured to respond to an incident electromagnetic radiation having a first wavelength by radiating away from said surface plasmon wavelength converter device an electromagnetic radiation having a second wavelength.

2. The surface plasmon wavelength converter device of claim 1, wherein said nanofeatures are configured to exhibit intensified fields in response to said surface plasmon waves generated at one or more surfaces of said metallic film.

3. The surface plasmon wavelength converter device of claim 1, wherein said at least one of said centers is disposed within approximately 500 nm or less of at least one of said nanofeatures.

4. The surface plasmon wavelength converter device of claim 1, further comprising a support layer adjacent a selected one of said metallic film and said wavelength conversion layer.

5. The surface plasmon wavelength converter device of claim 1, wherein a thickness of said metallic film is configured to allow coupling between a plasmon wave on said metallic film first surface and a plasmon wave on said metallic film second surface.

6. The surface plasmon wavelength converter device of claim 5, wherein said thickness of said metallic film is less than about ten skin depths at said first wavelength.

7. The surface plasmon wavelength converter device of claim 1, wherein at least one of said plurality of nanofeatures has a dielectric constant different than a dielectric constant of said metallic film.

8. The surface plasmon wavelength converter device of claim 1, wherein at least one of said plurality of nanofeatures comprises a metal of different composition than a metal of said metallic film.

9. The surface plasmon wavelength converter device of claim 1, wherein at least one of said plurality of nanofeatures comprises a dielectric material.

10. The surface plasmon wavelength converter device of claim 1, wherein at least one of said plurality of nanofeatures has a diameter in a range of approximately 10 nm to 10,000 nm.

11. The surface plasmon wavelength converter device of claim 1, wherein said plurality of nanofeatures are configured in an array having a spacing between nearest neighbors of said plurality of nanofeatures in a range of about 10 nm to 10,000 nm.

12. The surface plasmon wavelength converter device of claim 1, wherein said metallic film comprises a metal selected from the group of metals consisting of silver, gold, copper, and aluminum.

13. The surface plasmon wavelength converter device of claim 1, wherein said wavelength conversion layer includes a lanthanide dopant.

14. The surface plasmon wavelength converter device of claim 13, wherein said lanthanide dopant comprises a selected one of erbium, ytterbium, praseodymium, europium, cerium, and thulium

15. An integrated solar cell, comprising:
a surface plasmon wavelength converter device according to claim 1 having at least one solar cell layer optically coupled thereto, and
a first positive electrical terminal and a second negative terminal, said first positive electrical terminal and said second negative terminal configured to provide an electrical current and an electrical voltage as output signals.

16. The integrated solar cell of claim 15, further comprises at least one additional second surface plasmon wavelength converter device according to claim 1, said additional second surface plasmon wavelength converter device optically coupled to said solar cell.

17. The integrated solar cell of claim 15, wherein a material configured to exhibit optical transparency within a selected wavelength range is configured to encapsulate said solar cell system.

18. A surface plasmon wavelength converter device, comprising:
a metallic film having a plurality of nanofeatures, said metallic film having a metallic film first surface and a metallic film second surface; and
at least one center disposed in at least one of said plurality of nanofeatures;
wherein said surface plasmon wavelength converter device is configured to respond to an incident electromagnetic radiation having a first wavelength by radiating away from said surface plasmon wavelength converter device an electromagnetic radiation having a second wavelength.

19. The surface plasmon wavelength converter device of claim 18, wherein said at least one of said centers is disposed within approximately 500 nm or less of at least one of said nanofeatures.

20. The surface plasmon wavelength converter device of claim 18, wherein nanofeatures are configured to exhibit intensified fields in response to said surface plasmon waves generated at one or more surfaces of said metallic film.

21. The surface plasmon wavelength converter device of claim 18, further comprising a support layer adjacent a selected one of said metallic film and said wavelength conversion layer.

22. The surface plasmon wavelength converter device of claim 18, wherein a thickness of said metallic film is configured to allow coupling between a plasmon wave on said metallic film first surface and a plasmon wave on said metallic film second surface.

23. The surface plasmon wavelength converter device of claim 22, wherein said thickness of said metallic film is less than about ten skin depths at said first wavelength.

24. The surface plasmon wavelength converter device of claim 18, wherein at least one of said plurality of nanofeatures has a dielectric constant different than a dielectric constant of said metallic film.

25. The surface plasmon wavelength converter device of claim 18, wherein at least one of said plurality of nanofeatures comprises a metal of different composition than a metal of said metallic film.

26. The surface plasmon wavelength converter device of claim 18, wherein at least one of said plurality of nanofeatures comprises a dielectric material.

27. The surface plasmon wavelength converter device of claim 18, wherein at least one of said plurality of nanofeatures has a diameter in a range of approximately 10 nm to 10,000 nm.

28. The surface plasmon wavelength converter device of claim 18, wherein said plurality of nanofeatures are configured in an array having a spacing between nearest neighbors of said plurality of nanofeatures in a range of approximately 10 nm to 10,000 nm.

29. The surface plasmon wavelength converter device of claim 18, wherein said metallic film comprises a metal selected from the group of metals consisting of silver, gold, copper, and aluminum.

30. The surface plasmon wavelength converter device of claim 18, wherein said wavelength conversion layer includes a lanthanide dopant.

31. The surface plasmon wavelength converter device of claim 30, wherein said lanthanide dopant comprises a selected one of erbium, ytterbium, praseodymium, europium, cerium, and thulium.

32. An integrated solar cell, comprising:
a surface plasmon wavelength converter device according to claim 18 having at least one solar cell layer optically coupled thereto, and
a first positive electrical terminal and a second negative terminal, said first positive electrical terminal and said second negative terminal configured to provide an electrical current and an electrical voltage as output signals.

33. The integrated solar cell of claim 32, further comprises at least one additional second surface plasmon wavelength converter device according to claim 18, said additional second surface plasmon wavelength converter device.

34. The integrated solar cell of claim 32, wherein a material configured to exhibit optical transparency within a selected wavelength range is configured to encapsulate said solar cell system.

35. A surface plasmon wavelength converter device comprising:
a transparent conductive oxide (TCO) film having a plurality of metallic nanofeatures, said TCO film having a TCO film first surface and a TCO film second surface; and
a wavelength conversion layer having a plurality of centers, said wavelength conversion layer disposed adjacent to and optically coupled to said first surface of said TCO film, and
wherein said surface plasmon wavelength converter device is configured to respond to an incident electromagnetic radiation having a first wavelength by radiating away from said surface plasmon wavelength converter device an electromagnetic radiation having a second wavelength.

36. A surface plasmon wavelength converter device comprising:
a transparent conductive oxide (TCO) film having a plurality of metallic nanofeatures, said TCO film having a TCO film first surface and a TCO film second surface; and
at least one center disposed in at least one of said plurality of metallic nanofeatures;
wherein said surface plasmon wavelength converter device is configured to respond to an incident electromagnetic radiation having a first wavelength by radiating away from said surface plasmon wavelength converter device an electromagnetic radiation having a second wavelength.
